(19) United States
(12) Patent Application Publication
(10) Pub. No.: US 2023/0133753 A1
(43) Pub. Date: May 4, 2023

(54) SINGLE-AXIS INERTIAL SENSOR MODULE WITH INTERPOSER

(71) Applicant: Teledyne Scientific & Imaging, LLC, Thousand Oaks, CA (US)

(72) Inventors: Jeffrey F. DeNatale, Thousand Oaks, CA (US); Philip A. Stupar, Oxnard, CA (US)

(21) Appl. No.: 17/453,097

(22) Filed: Nov. 1, 2021

(51) Int. Cl. B81B 7/00

(52) U.S. Cl. CPC B81B 7/0048; B81B 7/007; B81B 7/0087; B81B 2201/0242; B81B 2201/0235

(57) ABSTRACT

A sensor module including a microelectromechanical systems (“MEMS”) gyroscope resonator and an accelerometer positioned adjacent the MEMS gyroscope resonator is disclosed herein. The MEMS gyroscope resonator and accelerometer can be co-fabricated on a sensor die and a control circuit can be electrically coupled to the sensor die. The control circuit can be configured to receive signals from and control the MEMS gyroscope resonator and the accelerometer. An interposer can be positioned between and mechanically coupled to the sensor module and a substrate, wherein the interposer is configured to relieve stresses imposed by an operating environment on the sensor module and the substrate.

### FIELD

The present disclosure is generally related to inertial measurement units (“IMUs”) and, more particularly, is directed to an interposer for a compact inertial measurement unit that uses a microelectromechanical systems (“M EMS”) gyroscope.

### SUMMARY

The following summary is provided to facilitate an understanding of some of the innovative features unique to the aspects disclosed herein and is not intended to be a full description. A full appreciation of the various aspects can be gained by taking the entire specification, claims, and abstract as a whole.

In various aspects, a sensor module is disclosed. The sensor module can include a microelectromechanical systems (“MEMS”) gyroscope resonator and an accelerometer. In some non-limiting aspects, the accelerometer can be a resonant accelerometer positioned adjacent the MEMS gyroscope resonator. The MEMS gyroscope resonator and accelerometer can be co-fabricated on a sensor die and a control circuit can be electrically coupled to the sensor die. The control circuit can be configured to receive signals from and control the MEMS gyroscope resonator and the accelerometer. An interposer can be positioned between and mechanically coupled to the sensor module and a substrate, wherein the interposer is configured to relieve stresses imposed by an operating environment on the sensor module and the substrate.

In various aspects, an inertial measurement unit (“IMU”) is disclosed. The IMU can include a plurality of single-axis sensor modules, wherein each of the plurality of single-axis sensor modules is mounted to a plurality of orthogonal surfaces. Each of the plurality of single-axis sensor modules can be configured to be contained within a common enclosure. Each of the plurality of single-axis sensor modules can include: a sensor die including a microelectromechanical systems (“MEMS”) gyroscope resonator and an accelerometer positioned adjacent the MEMS gyroscope resonator. The MEMS gyroscope resonator and accelerometer can be co-fabricated on the sensor die. The single-axis sensor modules can further include a control circuit electrically coupled to the sensor die, wherein the control circuit is configured to receive signals from and control MEMS gyroscope resonator and the accelerometer; and an interposer positioned between and mechanically coupled to the sensor module and a substrate. The interposer can be configured to relieve stresses imposed by an operating environment on the sensor module and the substrate.

In various aspects, a method of mitigating mechanical stresses of a sensor module within an IMU is disclosed. The method can include monitoring, via a temperature sensor, a thermal condition within a sensor module. The sensor module can include a control circuit, and the sensor module can be mechanically separated from a substrate via an interposer. The method can further include altering the thermal condition within the sensor module by controlling, via the control circuit, a heater positioned proximate to the sensor module.

In various aspects, a method of manufacturing an IMU subassembly is disclosed. The method can include fabricating a sensor module by co-fabricating on a sensor die a MEMS gyroscope resonator and a resonant accelerometer positioned adjacent the MEMS gyroscope resonator. The method can further include electrically coupling a control circuit to the sensor die as well as positioning and mechanically coupling an interposer between the sensor module and a substrate. The interposer can be configured to relieve stresses imposed by an operating environment on the sensor module and the substrate.

These and other features and characteristics of the present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF THE DRAWINGS

Various features of the aspects described herein are set forth with particularity in the appended claims. The various aspects, however, both as to organization and methods of operation, together with advantages thereof, may be understood in accordance with the following description taken in conjunction with the accompanying drawings as follows:

FIG. 1 illustrates a block diagram of a compact, navigation-grade inertial measurement unit (“IMU”), in accordance with at least one non-limiting aspect of the present disclosure;

FIG. 2 illustrates a portion of a single-axis sensor module configured for use in the compact navigation-grade IMU of FIG. 1, in accordance with at least one non-limiting aspect of the present disclosure;

FIG. 3 illustrates an assembly view of a subassembly of the IMU of FIG. 1 including a mechanical interposer configured to bond the single-axis sensor module of FIG. 2 to a substrate, in accordance with at least one non-limiting aspect of the present disclosure;

FIG. 4 illustrates an isometric view of the mechanical interposer of FIG. 3, in accordance with at least one non-limiting aspect of the present disclosure;

FIG. 5 illustrates an side view of the subassembly of FIG. 3, in accordance with at least one non-limiting aspect of the present disclosure;

FIG. 6 illustrates an assembly view of a subassembly of the IMU of FIG. 1 including another mechanical interposer configured to bond the single-axis sensor module of FIG. 2 to a substrate, in accordance with at least one non-limiting aspect of the present disclosure;

FIG. 7 illustrates a top view of the mechanical interposer of FIG. 6, in accordance with at least one non-limiting aspect of the present disclosure;

FIG. 8 illustrates a side view of the subassembly of FIG. 6, in accordance with at least one non-limiting aspect of the present disclosure;

FIG. 9 illustrates a simulated stress distribution of the mechanical interposer of FIGS. 6-8, in accordance with at least one non-limiting aspect of the present disclosure;

FIG. 10 illustrates a sectioned side view of an electrical interposer of the single-axis sensor module of FIG. 2, in accordance with at least one non-limiting aspect of the present disclosure;

FIG. 11 illustrates a logic flow diagram of a method of mitigating stresses within the IMU of FIG. 1, in accordance with at least one non-limiting aspect of the present disclosure; and

FIG. 12 illustrates a logic flow diagram of a method of fabricating a sensor module for use within the IMU of FIG. 1, in accordance with at least one non-limiting aspect of the present disclosure.

Corresponding reference characters indicate corresponding parts throughout the several views. The exemplifications set out herein illustrate various aspects of the invention, in one form, and such exemplifications are not to be construed as limiting the scope of the invention in any manner.

### DETAILED DESCRIPTION

Numerous specific details are set forth to provide a thorough understanding of the overall structure, function, manufacture, and use of the aspects as described in the disclosure and illustrated in the accompanying drawings. Well-known operations, components, and elements have not been described in detail so as not to obscure the aspects described in the specification. The reader will understand that the aspects described and illustrated herein are non-limiting examples, and thus it can be appreciated that the specific structural and functional details disclosed herein may be representative and illustrative. Variations and changes thereto may be made without departing from the scope of the claims. Furthermore, it is to be understood that such terms as “forward”, “rearward”, “left”, “right”, “upwardly”, “downwardly”, and the like are words of convenience and are not to be construed as limiting terms.

Before explaining various aspects of the interposer in detail, it should be noted that the illustrative examples are not limited in application or use to the details of disclosed in the accompanying drawings and description. It shall be appreciated that the illustrative examples may be implemented or incorporated in other aspects, variations, and modifications, and may be practiced or carried out in various ways. Further, unless otherwise indicated, the terms and expressions employed herein have been chosen for the purpose of describing the illustrative examples for the convenience of the reader and are not for the purpose of limitation thereof.

Specifically, it shall be appreciated that the term “interposer” shall be construed as any component specifically configured to be positioned intermediate two components (e.g., a housing, a substrate, a sensor die, and a control circuit, such as a microprocessor and/or an application specific integrated circuit (ASIC), etc.) of a larger system to achieve a desired electrical and/or mechanical relationship between those components. For example, an interposer can be a through-silicon via (“TSV”) based interposer configured to establish a particular electrical relationship between components, or a stress-relieving interposer configured to achieve a desired mechanical relationship between components. In one aspect, the interposer can be provided in a form factor suitable for attachment to a substrate or printed circuit board and thus, can be specifically configured to alter the mechanical and/or electrical interface between the component and substrate or printed circuit board. Furthermore, although the present disclosure discusses the use of interposers to improve the mechanical and/or electrical interface between a gyroscope and a printed circuit board, these examples are merely illustrative and not intended to be limiting. Accordingly, it shall be appreciated that the interposers described herein can provide similar benefits for numerous applications, including enhancing the interface between a substrate or printed circuit board and virtually any mechanical and/or electrical component.

Inertial measurement units (“IMUs”) are, generally, electronic devices configured to measure a specific force, angular rate, and/or orientation of a body (e.g., a fuselage, a spacecraft bus, etc.) using one or more multi-axis measuring components (e.g., accelerometers, gyroscope resonators, magnetometers, etc.). Known IMU designs typically compartmentalize such components into discrete vacuum packages, which are subsequently integrated with board-level electronics and mounted on orthogonal supports. Such designs preserve IMU performance by physically separating the various sensors and circuits to mitigate parasitic noise and interference. In other words, known IMU designs are accurate, but are neither streamlined nor geometrically efficient.

IMUs, however, are commonly implemented in mission critical environments to maneuver vehicles that are continually decreasing in size (e.g., aircrafts, spacecrafts, etc.). In order to accommodate for these changing requirements, IMU accuracy must be preserved (if not improved) in a more economical geometric design and form factor. In other words, circuits that were previously vacuum packed and/or compartmentalized can be integrated while continuing to mitigate inter-circuit noise, sensor drift, and thermal stresses and gradients. Such electrical and mechanical stresses only increase as the size of an IMU decreases, as circuits are routed closer together and mechanical and thermal excitations become more consequential. Accordingly, there is a need for improved IMU components that optimize performance and size—characteristics that can compromise each other if not properly managed.

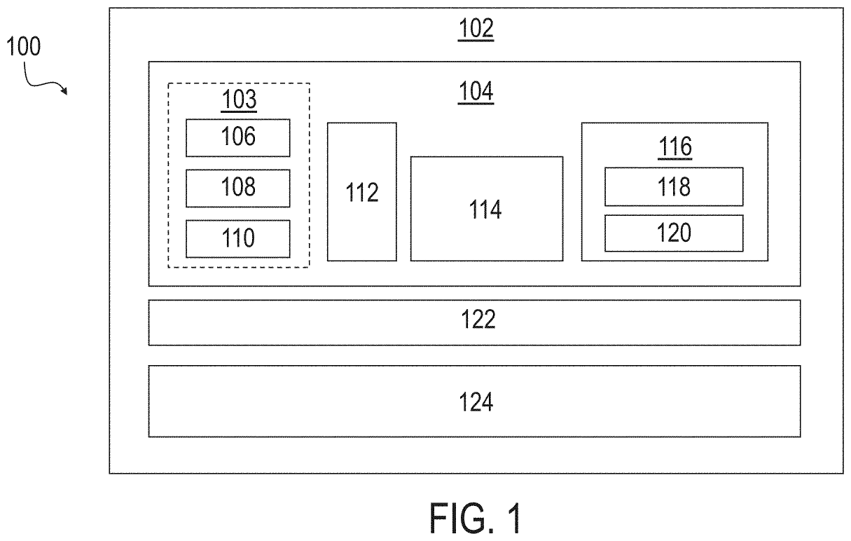

Referring now to FIG. 1, a block diagram of a compact, navigation-grade inertial measurement unit (“IMU”) 100 is depicted in accordance with at least one non-limiting aspect of the present disclosure. According to the non-limiting aspect of FIG. 1, the IMU can include one or more sensor modules 102. For example, the sensor module 102 can be single-axis and oriented within the IMU 100 and orthogonally positioned relative to two other sensor modules. According to the non-limiting aspect of FIG. 1, the sensor module 102 can include a sensor subassembly 104 configured to be coupled to a substrate 124 via a mechanical interposer 122. According to the non-limiting aspect of FIG. 1, the sensor die 104 can include one or more sensors, including, but not limited to, a temperature sensor 106, a gyroscope 108, and/or an accelerometer 110. For example, the sensor subassembly 104 can include a microelectromechanical systems (“MEMS”) gyroscope resonator 108 and a resonant accelerometer 110. According to some non-limiting aspects, the MEMS gyroscope resonator 108 and the resonant accelerometer 110 can be co-fabricated on the same sensor die 103.

In further reference to FIG. 1, the sensor subassembly 104 can further include an analog front end 112, a control circuit 114, and/or a digital interface 116. According to the non-limiting aspect of FIG. 1, the control circuit 114 can be configured to perform signal processing, calibration, and/or other processing functions according to user preference and/or intended application. The digital interface 116, for example, can include a universal asynchronous receiver-transceiver (“UART”) and/or a serial peripheral interface (“SPI”), although the present disclosure contemplates other interfaces that might be desirable according to the intended application and/or user preference. The sensor subassembly 104 can be coupled to a mechanical interposer 122 configured to mitigate stresses that would otherwise be transposed between the sensor subassembly 104 and the substrate 124 of the IMU 100. As will be described herein, the mechanical interposer can be specifically configured to mitigate and/or eliminate mechanical stresses (e.g., thermal stresses, vibrational excitations, etc.) on the sensor subassembly 104, thereby reducing the signal errors that result when circuits are condensed. Accordingly, the overall volume of IMU 100 can be significantly reduced while preserving IMU 100 performance.

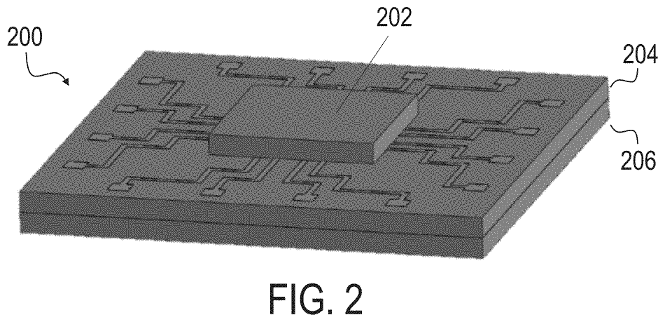

Referring now to FIG. 2, a perspective view of a single-axis sensor module 200 configured for use within the IMU 100 of FIG. 1 is depicted in accordance with at least one non-limiting aspect of the present disclosure. According to the non-limiting aspect of FIG. 2, the single-axis sensor module 200—which can include the sensor subassembly 102 of FIG. 1—can include a control circuit 202, a sensor die 206, both of which are configured for single-die integration into a common housing. The control circuit 202 may be an integrated circuit, a custom circuit, and in some aspects an ASIC. The control circuit 202 can be electrically coupled to the sensor die 206 by an electrical interposer 204, although other means of electrical connections (e.g., wire-bonding, flip chips, etc.) are contemplated by the present disclosure. The sensor die 206 can include any combination of desired sensors, including a wide variety of gyroscopes (e.g., microelectromechanical systems (“MEMS”) sensors, other resonator-based gyroscopes, etc.), accelerometers (e.g., a differential resonant beams accelerometers (“DRBAs”), piezoelectric accelerometers, piezoresistive accelerometers, and capacitive accelerometers, etc.), magnetometers, and/or the like.

In further reference to FIG. 2, the control circuit 202 of FIG. 2 can be specifically configured to receive signals from the sensor die 206 via the electrical interposer 204 and can include a custom design configured to control and readout the various sensors on the sensor die 206 based, at least in part, on signals received from the sensor die 206. According to the non-limiting aspect of FIG. 2, the electrical interposer 204 can be configured to serve as an intermediate electrical interface that can route electrical signals from the sensor die 206 to the control circuit 202. As such, all electrical signals that are generated by the various sensors on the sensor die 206 can be routed up through the electrical interposer 204, which is electrically and mechanically coupled to the control circuit 202 for processing.

In various aspects, the single-axis sensor module 200 of FIG. 2 can include a single-chip sensor die 206 direct bonded to the control circuit 202 via the electrical interposer 204, which enables an ultra-compact, navigation grade capability, when integrated into the IMU 100 of FIG. 1. For example, the control circuit 202 of FIG. 2 can be directly bonded via a bump connection to the electrical interposer 204 and sensor die 206 of FIG. 2 via solder and/or a conductive polymer. It will be appreciated that the present disclosure contemplates other means of electrical and mechanical interconnection using other suitable electrical bonding compounds or alloys to achieve the same effect, including, but not limited to, wire bonds. Furthermore, each of the sensor die 206, electrical interposer 204, and control circuit 202 can be produced from materials that have similar mechanical properties, such as a coefficient of thermal expansion. Accordingly, each of the sensor die 206, the electrical interposer 204, and the control circuit 202 will experience a substantially uniform response to mechanical stresses created by reduced volumes, closely spaced circuit elements, and increased temperatures to reduce, for example, subsequent stresses between each of the three components 202, 204, 206. In some non-limiting aspects, the sensor die 206, the electrical interposer 204, and the control circuit 202 can be produced from the same material, such as silicon, to further reduce stresses.

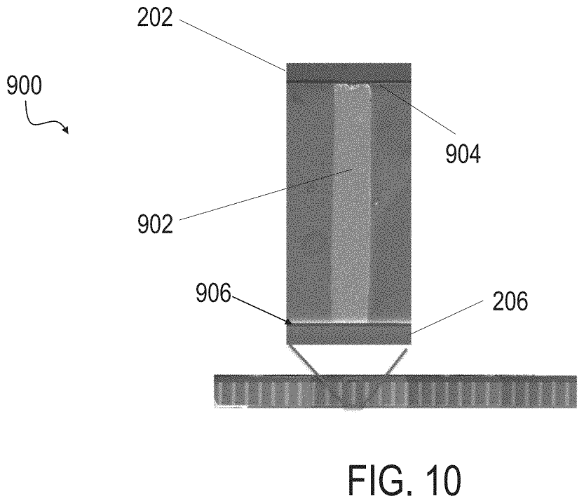

Accordingly, the single-axis sensor module 200 of FIG. 2 may be implemented in a form factor such that it can be contained within a common enclosure, and the sensor die 206, electrical interposer 204, and control circuit 202 can be specifically configured to reduce the stresses that have prohibited known devices from achieving high performances in reduced volumes. Specifically, the electrical interposer 204 can be specifically configured to reduce signal noise generated by the reduction of IMU 100 (FIG. 1) volume. For example the electrical interposer 204 can include a plurality of electrical interconnects, wherein each of the plurality of interconnects electrically couples an output of the sensor die to a corresponding output of the control circuit 202. Additionally and/or alternatively, a heater and/or temperature sensor can be positioned on the electrical interposer 204 to perform die-level thermal stabilization. An example of an electrical interposer 900 featuring interconnects 902, a thermal controller 904 (e.g., a heater or cooler), and temperature sensors 906 is depicted in FIG. 10. Accordingly, the electrical interposer 204 can be specifically configured to monitor temperature which may introduce thermal stresses, which stabilizes separation of circuits and thus, can reduce detrimental parasitics (e.g., electromagnetic interference (“EMI”), signal noise, etc.). In this manner, the electrical interposer 204 can facilitate high IMU 100 (FIG. 1) performance in spite of the reduction in spacing between circuits and electrical lines of the sensor die 206 and the control circuit 202.

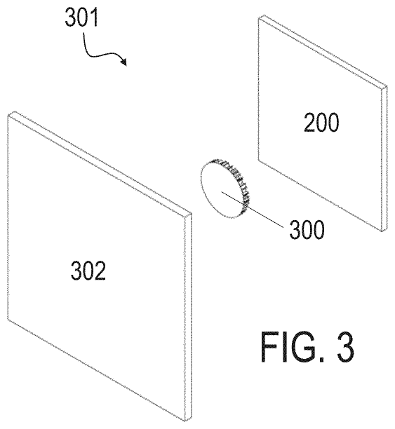

Referring now to FIG. 3, an assembly view of a subassembly 301 of the IMU 100 of FIG. 1 including a mechanical interposer 300 configured to bond the single-axis sensor module 200 of FIG. 2 to a substrate 302 is depicted in accordance with at least one non-limiting aspect of the present disclosure. The IMU 100 (FIG. 1) can include one or more substrates 302 oriented to sense—and generate signals associated with—accelerations and/or motions along a desired axis. For example, the IMU 100 of FIG. 1, can include three orthogonally mounted sensor modules 102 and thus, is configured for three-axis sensing. As such, substrates 302 can be particularly arranged based on user preferences and/or intended application.

According to the non-limiting aspect of FIG. 3, the mechanical interposer 300 can be interposed between—and configured to mechanically couple—the single-axis sensor module 200 of FIG. 2 and the substrate 302 of the IMU 100 of FIG. 1. As such, the mechanical interposer 300 can be uniquely positioned and further configured to mitigate stresses that would otherwise be transposed between the single-axis sensor module 200 of FIG. 2 and the substrate 302 of the IMU 100 of FIG. 1 to facilitate, for example, a further reduction of IMU 100 volume while preserving IMU 100 (FIG. 1) performance by reducing errors associated with the adverse effects of shrinking and/or condensed circuits (e.g., thermal stresses, vibrational excitations, etc.).

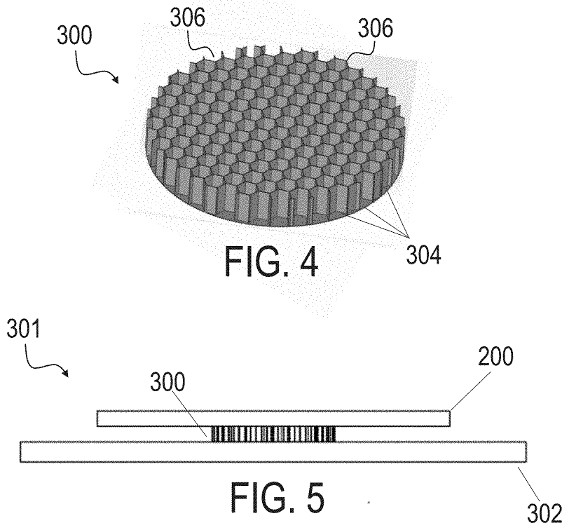

Referring now to FIG. 4, an isometric view of the mechanical interposer 300 of FIG. 3 is depicted in accordance with at least one non-limiting aspect of the present disclosure. According to the non-limiting aspect of FIG. 4, the mechanical interposer 300 can include a plurality of walls 304 configured to define a plurality of cavities 306. According to the non-limiting aspect of FIG. 4, the cavities 306 can be hexagonally configured to collectively form a honeycomb capable of distributing mechanical stresses and forces evenly. The hexagonal cavities 306 can further increase the surface area of the mechanical interposer 300 to enhance, for example, the convective and radiative properties of the mechanical interposer 300. In one aspect, the mechanical interposer 300 of FIG. 4 can be implemented to mitigate mechanical disturbances and mitigate mechanical stresses that are created in either the substrate 302, the single-axis sensor module 200, and prevent them from adversely effecting performance of the IMU 100 (FIG. 1).

In further reference to FIG. 4, the hexagonal cavities 306 can effectively mitigate mechanical stresses within the IMU 100 (FIG. 1) and thus, protect the single-axis sensor module 200 (FIG. 2), including the ASIC 202 (FIG. 2), the electrical interposer 204 (FIG. 2), and the sensor die (206) by tailoring the in plane stiffness of the mechanical coupling element. According to other non-limiting aspects of the present disclosure, the plurality of walls 304 of the mechanical interposer 300 can be configured to form any number of geometrical configurations, including those of circular, rectangular, triangular cross-section, square, rectangular, pentagonal, or other polygonal shapes that include seven or more sides, for example. Additionally and/or alternatively, in other non-limiting aspects of the present disclosure, the plurality of walls 304 can be reconfigured to form fewer or more cavities 306. In other words, the volume of each cavity 306 can be reduced or increased to further attenuate the mechanical stress-relieving properties of the mechanical interposer 300.

Referring now to FIG. 5, a side view of the subassembly 301 of FIG. 3 is depicted in accordance with at least one non-limiting aspect of the present disclosure. According to the non-limiting aspect depicted in FIG. 5, the single-axis sensor module 200, the mechanical interposer 300, and the substrate 302 can be manufactured from materials that have similar mechanical properties, such as a desirable coefficient of thermal expansion. For example, the substrate 302 can be produced from alumina ceramic, the mechanical interposer can be produced from the same material, such as silicon, and the single-axis sensor module 200 can be produced from the same material, such as silicon. According to other non-limiting aspects of the present disclosure, other materials can be selected to reduce mechanical stresses throughout the subassembly according to user preference and/or intended application such as a variety of ceramic materials, including beryllium oxide (BeO), aluminum nitride (AlN), and fused silica commonly used for substrates, for example. Similar to the sensor die 206 (FIG. 2), electrical interposer 204 (FIG. 2), and control circuit 202 (FIG. 2) of the single-axis sensor module 200, this can further reduce and/or eliminate mechanical stresses that are generated between components of the subassembly.

According to some non-limiting aspects of the present disclosure, the subassembly 301 of FIG. 5 can be assembled via a die attach process bonding, such as soldering, for example, between the single-axis sensor module 200, the mechanical interposer 300, and the substrate 302. In one aspect, the mechanical interposer 300 may be configured to enable the removal of bonding material to further reduce the introduction of inter-component stresses. Moreover, the mechanical interposer 300 of FIGS. 3-5 can work with numerous substrates and a wide variety of component mounting and multi-process assembly technologies, including flip-chip, flex-chip, surface-mount technology, and three-dimensional stacked dies, among others. The hexagonal configuration of the mechanical interposer 300 of FIGS. 3-5 is efficient and embodies a favorable strength to weight ratio. Furthermore, when coupled with the single-axis sensor module 200 and the substrate 302, the subassembly 301 has, in effect, two surface sheets parallel to each other to provide flexural immobility, while the mechanical interposer provides compressive resistance, which makes it an optimal mechanical interposer for composite packaging assemblies.

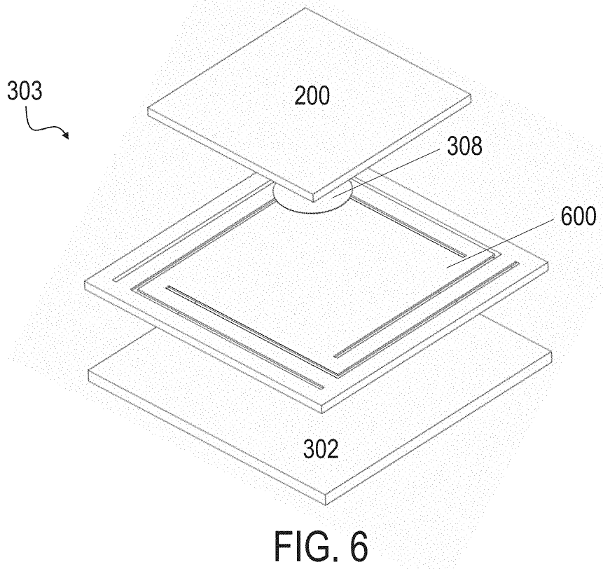

Referring now to FIG. 6, an assembly view of a subassembly 303 of the IMU 100 of FIG. 1 including another mechanical interposer 600 configured to bond the single-axis sensor module 200 of FIG. 2 to a substrate 302 is depicted in accordance with at least one non-limiting aspect of the present disclosure. As previously mentioned, the IMU 100 (FIG. 1) can include one or more substrates 302 oriented to sense—and generate signals associated with—accelerations and/or motions along a desired axis. For example, the IMU 100 of FIG. 1, can include three orthogonally mounted sensor modules 102 and thus, is configured for three-axis sensing. As such, substrates 302 can be particularly arranged based on user preferences and/or intended application.

According to the non-limiting aspect of FIG. 6, the mechanical interposer 600 can be interposed between—and configured to mechanically couple—the single-axis sensor module 200 of FIG. 2 and the substrate 302 of the IMU 100 of FIG. 1. As such, the mechanical interposer 600 can be uniquely positioned and further configured to mitigate stresses that would otherwise be transposed between the single-axis sensor module 200 of FIG. 2 and the substrate 302 of the IMU 100 of FIG. 1 to facilitate, for example, a further reduction of IMU 100 volume while preserving IMU 100 (FIG. 1) performance by reducing errors associated with the adverse effects of shrinking and/or condensed circuits (e.g., thermal stresses, vibrational excitations, etc.). Additionally and/or alternatively, the subassembly 303 of FIG. 6 can include solder 308 for use via a die attach process to attach the single-axis sensor module 200, the mechanical interposer 300, and the substrate 302.

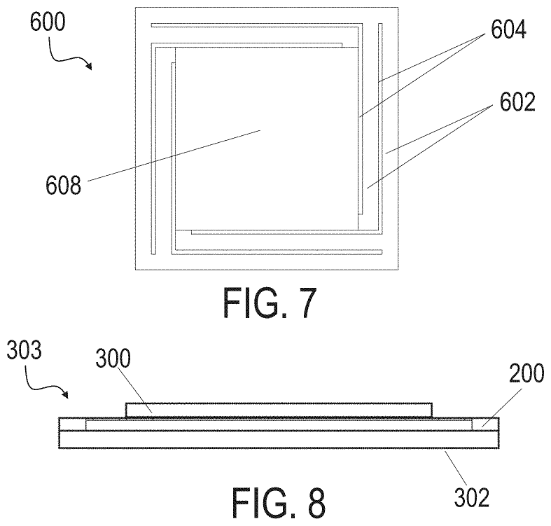

Referring now to FIG. 7, a top view of the mechanical interposer 600 of FIG. 6 is depicted in accordance with at least one non-limiting aspect of the present disclosure. According to the non-limiting aspect of FIG. 7, the mechanical interposer 600 can include a plurality of spring elements 602 separated from a solid core 608 by a plurality of spaces 606. It shall be appreciated that the spring elements 602, core 608, and spaces 604 can be dimensionally configured to achieve a desired spring coefficient to account for mechanical stresses such as vibrational excitations and/or thermal expansions to distribute, for example, mechanical stresses and forces evenly across the subassembly 303. The spring elements 602, core 608, and spaces 604 can further increase the surface area of the mechanical interposer 600 to enhance, for example, the convective and radiative properties of the mechanical interposer 600. In other words, the mechanical interposer 600 of FIG. 7, can also be implemented to mitigate mechanical disturbances and stresses that are created in either the substrate 302, the single-axis sensor module 200, and prevent them from adversely effecting performance of the IMU 100 (FIG. 1). In the aspect illustrated in FIGS. 6 and 7, the spring elements 602 may be formed by cutting or etching grooves or slots in the solid core 608 of the mechanical interposer 600.

In further reference to FIG. 7, the spring elements 602, core 608, and spaces 606 include a square (or rectangular) configuration that helixes inwards towards the core to effectively mitigate mechanical stresses within the IMU 100 (FIG. 1) and thus, protect the single-axis sensor module 200 (FIG. 2), including the control circuit 202 (FIG. 2), the electrical interposer 204 (FIG. 2), and the sensor die (206). According to other non-limiting aspects, the mechanical interposer 600 can include any number of geometric configurations, as long as the spring elements 602, core 608, and spaces 606 collectively helix inwards to achieve the desired elasticity. For example, according to other non-limiting aspects, the mechanical interposer 600 can include numerous geometrical configurations, including those of circular, rectangular, and/or triangular cross-section, depending on user preference and/or intended application. Additionally and/or alternatively, in other non-limiting aspects, the spring elements 602 can be reconfigured to form fewer or more spaces 606, which would attenuate the elasticity and/or rigidity of the mechanical interposer 600. In other words, the spring elements 602, core 608, and spaces 606 of FIG. 7 can be altered or increased to further attenuate the mechanical stress-relieving properties of the mechanical interposer 600.

Referring now to FIG. 8, a side view of the subassembly 303 of FIGS. 6 and 7 is depicted in accordance with at least one non-limiting aspect of the present disclosure. According to the non-limiting aspect of FIG. 8, the single-axis sensor module 200, the mechanical interposer 600, and the substrate 302 can be manufactured from materials that have similar mechanical properties, such as a coefficient of thermal expansion. For example, the substrate 302 can be produced from alumina ceramic, the mechanical interposer can be produced from silicon, and the single-axis sensor module 200 can be produced from silicon. According to other non-limiting aspects, other materials can be selected to reduce mechanical stresses throughout the subassembly according to user preference and/or intended application. Similar to the sensor die 206 (FIG. 2), electrical interposer 204 (FIG. 2), and control circuit 202 (FIG. 2) of the single-axis sensor module 200, this can further assist in reducing and/or eliminating mechanical stresses that are generated between components of the subassembly.

According to some non-limiting aspects of the present disclosure, the subassembly 303 of FIG. 8 can be assembled via a die attach process implementing soldering between the single-axis sensor module 200, the mechanical interposer 600, and the substrate 302. In one aspect, the mechanical interposer 600 enables the removal of such soldering, which further reduces the introduction of inter-component stresses. Moreover, the mechanical interposer 600 of FIGS. 6-8 can work with numerous substrates and a wide variety of component mounting and multi-process assembly technologies, including flip-chip, flex-chip, surface-mount technology, and three-dimensional stacked dies.

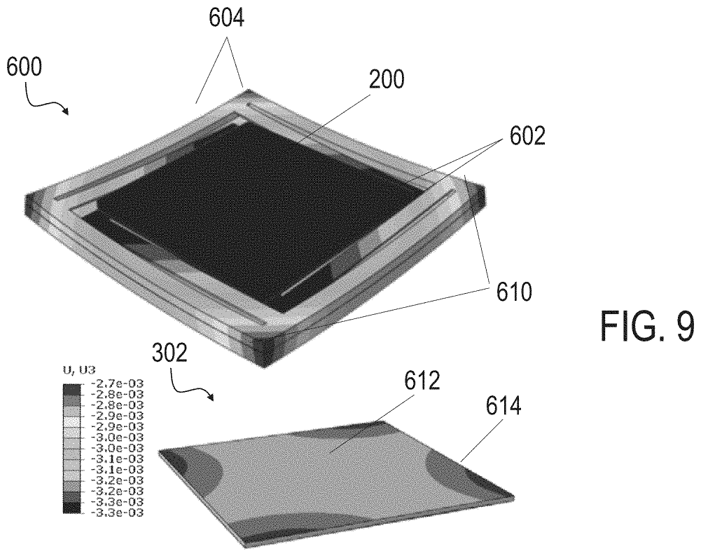

Referring now to FIG. 9, a simulated deflection distribution of the mechanical interposer 600 of FIGS. 6-8 is depicted in accordance with at least one non-limiting aspect of the present disclosure. According to the non-limiting aspect of FIG. 9, the mechanical interposer 600—and more specifically, the configuration of spring elements 602 and spaces 604—can isolate stress-induced deflections to the outer corners 610 of the mechanical interposer 600. Due to the elasticity of the spring elements 602, the solid core 608 of the mechanical interposer 600 is subjected to fewer mechanical stresses and thus, a sensor module 200, when coupled to the solid core 608, is consequently subjected to fewer mechanical stresses. Likewise, the substrate 302 is subjected to fewer stresses, which are concentrated on the outer corners 614, as the core 612 of the substrate 302 undergoes significantly less displacement. In some non-limiting aspects of the present disclosure, the mechanical interposer 600 of FIGS. 6-9 can distribute mechanical stresses such that the corners 302 undergo a maximum out of plane displacement of approximately −2.7e⁻⁰³ millimeters, U3, while the displacement of the center of 302 is approximately −3.3e⁻⁰³ millimeters, U3, for an approximate total displacement differential of approximately 0.6 micrometers.

Referring now to FIG. 10 a sectioned, side view of the electrical interposer 900 of the single-axis sensor module 200 of FIG. 2 is depicted in accordance with at least one non-limiting aspect of the present disclosure. According to the non-limiting aspect of FIG. 10, the electrical interposer 900 can be specifically configured to compensate thermal stresses, which stabilizes separation of circuits and thus, can reduce detrimental parasitics (e.g., electromagnetic interference (“EMI”), signal noise, etc.). For example, the electrical interposer 900 of FIG. 10 can include a plurality of interconnects 902 that electrically couple a portion of the control circuit 202 (FIG. 2) to a portion of the sensor die 206 (FIG. 2). In one aspect, the electrical interposer can further include a thermal controller 904 and/or a temperature sensor 906 electrically coupled to and configured to be controlled by the ASIC 202 (FIG. 2). As such, the electrical interposer 900 of FIG. 10 can be specifically configured to monitor thermal stresses, which stabilizes separation of circuits and thus, can reduce detrimental parasitics (e.g., electromagnetic interference (“EMI”), signal noise, etc.).

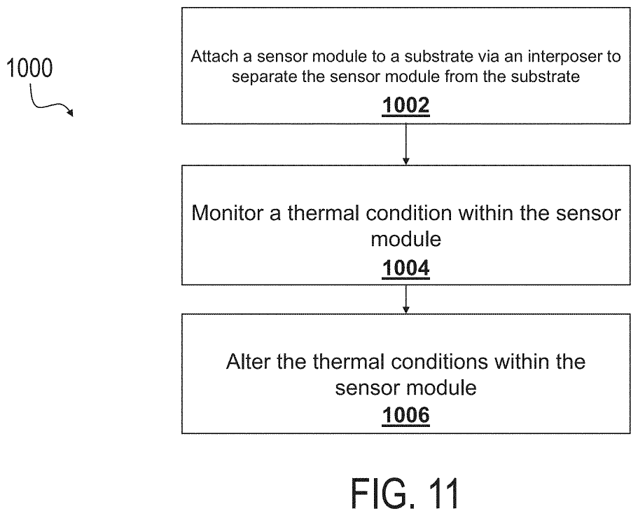

Referring now to FIG. 11, a logic flow diagram of a method 1000 of mitigating stresses within the IMU 100 of FIG. 1 is depicted in accordance with at least one non-limiting aspect of the present disclosure. According to the non-limiting aspect of FIG. 11, the method 1000 can include attaching 1002 a sensor module 200 (FIG. 2) to a substrate 302 (FIG. 3) via an interposer 300, such that the sensor module 200 (FIG. 2) includes a single-chip sensor die and a control circuit 202 (FIG. 2) is mechanically separated from the substrate 302 (FIG. 3). The method 1000 can further include monitoring 1004, via a temperature sensor 906 (FIG. 10), a thermal condition within the sensor module 200 (FIG. 2). The method 1000 can include altering 1006 the thermal conditions within the sensor module 200. This function may be accomplished by controlling, via the control circuit 202 (FIG. 2), a thermal controller 904 (FIG. 10) positioned within the sensor module 200 to alter, for example, the thermal condition within the sensor module 200. According to some non-limiting aspects, the method 1000 can include electrically coupling, via an electrical interposer 900 (FIG. 10), the single-chip sensor die 206 (FIG. 2) and the ASIC 202 (FIG. 2) from a substrate 302 (FIG. 3), wherein the temperature sensor 906 (FIG. 10) is positioned within the electrical interposer 900 (FIG. 10). According to still other non-limiting aspects, the electrical interposer 900 (FIG. 10) includes a plurality of electrical interconnects 902 (FIG. 10), wherein each interconnect of the plurality is configured to electrically couple a portion of the sensor die 206 (FIG. 2) to a portion of the control circuit 202 (FIG. 2).

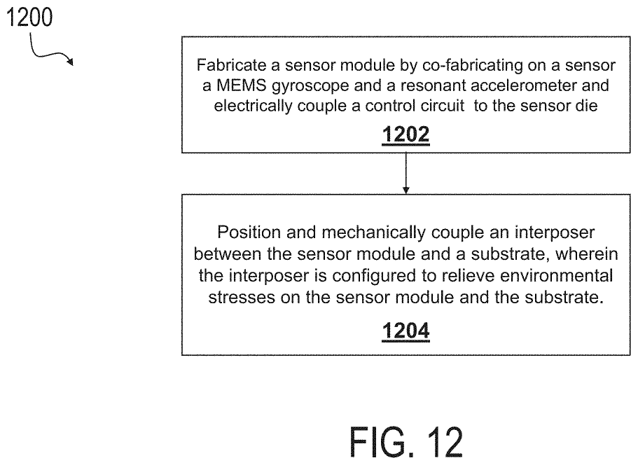

Referring now to FIG. 12, a flow diagram of a method 1200 of fabricating a sensor module configured to mitigate stresses within the IMU 100 of FIG. 1 is depicted in accordance with at least one non-limiting aspect of the present disclosure. According to the non-limiting aspect of FIG. 12, the method 1200 can include fabricating 1202 a sensor module by co-fabricating on a sensor die 103 (FIG. 1) a MEMS gyroscope 108 (FIG. 1) and a resonant accelerometer 110 (FIG. 1) and electrically coupling a control circuit 114 (FIG. 1) to the sensor die 103 (FIG. 1). The method 1200 can further include positioning and mechanically coupling 1204 an interposer 122 (FIG. 1) between the sensor module 102 (FIG. 1) and a substrate 124 (FIG. 1), wherein the interposer 122 (FIG. 1) is configured to relieve environmental stresses on the sensor module 102 (FIG. 1) and the substrate 124 (FIG. 1). According to some non-limiting aspects of the present disclosure, the method 1200 can further include fabricating a plurality of spring elements 602 (FIG. 6) on the interposer 600 (FIG. 6), wherein the interposer comprises a core 608 (FIG. 6) and the plurality of spring elements 602 (FIG. 6) are separated from the core 608 (FIG. 6) by a plurality of spaces 604 (FIG. 6) defined by the core 608 (FIG. 6). However, according to other non-limiting aspect of the present disclosure, the method 1200 can further include fabricating a plurality of walls 304 (FIG. 4) on the interposer 300 (FIG. 4), wherein the plurality of walls define a plurality of cavities 306 (FIG. 4) configured to distribute mechanical stresses between the sensor die 200 (FIG. 3) and the substrate 302 (FIG. 3).

In further reference to FIG. 12, the method 1200 can further include fabricating an electrical interposer 204 (FIG. 2) including a plurality of electrical interconnects, wherein each of the plurality of interconnects 902 (FIG. 10) electrically configured to couple at least a portion of the sensor die 206 (FIG. 2) to a portion of the control circuit 202 (FIG. 2). According to another non-limiting aspect of the present disclosure, the method 1200 can further include positioning a temperature sensor 906 (FIG. 10) between the sensor die 206 (FIG. 2) and the control circuit 202 (FIG. 2), and electrically coupling a thermal controller 904 (FIG. 10) to the temperature sensor, wherein the thermal controller 904 (FIG. 10) is configured to compensate for temperature changes in the sensor die 206 (FIG. 2) and the circuit 202 (FIG. 2).

The sensor modules and interposers disclosed herein can be implemented within a compact, navigation-grade inertial measurement unit in accordance with at least one non-limiting aspect of the present disclosure. According to some non-limiting aspects, the IMU can include a plurality of modules, wherein each module can contain a sensor 200 (FIG. 2) configured to measure a specific force, angular rate, and/or orientation of a body in a single axis. Specifically, the IMU can include three orthogonally mounted sensor modules and thus, can be configured for three-axis sensing. It shall be appreciated that an IMU that implements the sensors 200 (FIG. 2) and interposers 204 (FIG. 2), 300 (FIG. 3), and 600 (FIG. 6) disclosed herein can be reduced to a form factor defining a volume of approximately 1-5 cm³. Accordingly, the sensors 200 (FIG. 2) and interposers 204 (FIG. 2), 300 (FIG. 3), and 600 (FIG. 6) contemplated by the present disclosure can reduce the size of a conventional IMU without compromising performance.

Various aspects of the subject matter described herein are set out in the following numbered clauses:

Clause 1: A sensor module including: a sensor die including a microelectromechanical systems (“MEMS”) gyroscope resonator and an accelerometer positioned adjacent the MEMS gyroscope resonator; a control circuit electrically coupled to the sensor die, wherein the control circuit is configured to receive signals from and control the MEMS gyroscope resonator and the accelerometer; and an interposer positioned between and mechanically coupled to the sensor module and a substrate, wherein the interposer is configured to relieve stresses imposed by an operating environment on the sensor module and the substrate.

Clause 2: The sensor module according to clause 1, wherein the interposer includes a core and a plurality of spring elements separated from the core by a plurality of spaces defined by the core.

Clause 3: The sensor module according to clauses 1 or 2, wherein the interposer defines a spring coefficient and is configured to distribute mechanical stresses between the substrate and the control circuit.

Clause 4: The sensor module according to any of clauses 1-3, wherein the interposer includes a plurality of walls configured to define a plurality of cavities configured to distribute mechanical stresses between the sensor die and the control circuit.

Clause 5: The sensor module according to any of clauses 1-4, wherein the plurality of cavities define a hexagonal configuration.

Clause 6: The sensor module according to any of clauses 1-5, wherein the interposer defines a surface area configured to enhance radiation of thermal energy generated between the sensor die and the control circuit.

Clause 7: The sensor module according to any of clauses 1-6, further including an electrical interposer including a plurality of electrical interconnects, wherein each of the plurality of interconnects is configured to electrically couple at least a portion of the sensor die to a portion of the control circuit.

Clause 8. The sensor module according to any of clauses 1-7, wherein the electrical interposer has a coefficient of thermal expansion that is the same as a coefficient of thermal expansion of the sensor die and a coefficient of thermal expansion of the control circuit.

Clause 9: The sensor module according to any of clauses 1-8, further including: a temperature sensor positioned between the sensor die and the control circuit; and a thermal controller electrically coupled to the temperature sensor, wherein the thermal controller is configured to compensate for temperature changes in the sensor die and the control circuit.

Clause 10: The sensor module according to any of clauses 1-8, wherein the accelerometer is a resonant accelerometer that is co-fabricated with the MEMS gyroscope resonator.

Clause 11: An inertial measurement unit (IMU) including: a plurality of single-axis sensor modules, wherein each of the plurality of single-axis sensor modules is mounted to a plurality of orthogonal surfaces, wherein each of the plurality of single-axis sensor modules is configured to be contained within a common enclosure, wherein each of the plurality of single-axis sensor modules includes: a sensor die including a microelectromechanical systems (“MEMS”) gyroscope resonator and a accelerometer positioned adjacent the MEMS gyroscope resonator; a control circuit electrically coupled to the sensor die, wherein the control circuit is configured to receive signals from and control MEMS gyroscope resonator and the accelerometer; and an interposer positioned between and mechanically coupled to the sensor module and a substrate, wherein the interposer is configured to relieve stresses imposed by an operating environment on the sensor module and the substrate.

Clause 12: The IMU according to clause 11, wherein the plurality of single-axis sensor modules includes three sensor modules, wherein each of the three sensor modules is orthogonally oriented relative to the other two sensor modules.

Clause 13: The IMU according to either of clauses 11 or 12, wherein the interposer includes a core and a plurality of spring elements separated from the core by a plurality of spaces defined by the core.

Clause 14: The IMU according to any of clauses 11-13, wherein the interposer defines a spring coefficient and is configured to distribute mechanical stresses between the sensor die and the substrate.

Clause 15: The IMU according to any of clauses 11-14, wherein the interposer includes a plurality of walls configured to create a plurality of cavities configured to distribute mechanical stresses between the sensor module and the substrate.

Clause 16: The IMU according to any of clauses 11-15, wherein the cavities are hexagonally configured.

Clause 17: The IMU according to any of clauses 11-16, wherein the interposer includes a surface area configured to enhance radiation of thermal energy generated between the sensor die and the substrate.

Clause 18: The IMU according to any of clauses 11-17, further including an electrical interposer including a plurality of electrical interconnects, wherein each of the plurality of interconnects electrically couples at least a portion of the sensor die to a portion of the ASIC.

Clause 19: The IMU according to any of clauses 11-18, wherein the electrical interposer has a coefficient of thermal expansion that is the same as a coefficient of thermal expansion of the sensor die and a coefficient of thermal expansion of the ASIC.

Clause 20: The IMU according to any of clauses 11-19, further including: a temperature sensor positioned between the sensor die and the ASIC; and a thermal control element and electrically coupled to the temperature sensor, wherein the thermal controller is configured to compensate for temperature changes in the operating environment.

Clause 21: The IMU according to any of clauses 11-20, wherein the accelerometer is a resonant accelerometer that is co-fabricated with the MEMS gyroscope resonator.

Clause 22: A method of mitigating mechanical stresses within an inertial measurement unit (IMU), the method including: monitoring, via a temperature sensor, a thermal condition within a sensor module, wherein the sensor module includes a control circuit, and wherein the sensor module is mechanically separated from a substrate via an interposer; and altering the thermal condition within the sensor module by controlling, via the control circuit, a heater positioned proximate to the sensor module.

Clause 23: The method according to clause 22, further including: electrically coupling, via an electrical interposer, the sensor module and the circuit from the substrate; wherein the temperature sensor is positioned within the electrical interposer.

Clause 24: The method according to either of clauses 22 or 23, further including: electrically coupling a portion of the sensor module to a portion of the circuit via a plurality of electrical interconnects.

Clause 25: A method of manufacturing an inertial measurement unit (“IMU”) subassembly, the method including: fabricating a sensor module by co-fabricating on a sensor die a microelectromechanical systems (“MEMS”) gyroscope resonator and a accelerometer positioned adjacent the MEMS gyroscope resonator and electrically coupling a control circuit to the sensor die; and positioning and mechanically coupling an interposer between the sensor module and a substrate, wherein the interposer is configured to relieve stresses imposed by an operating environment on the sensor module and the substrate.

Clause 26: The method according to clause 25, further including fabricating a plurality of spring elements on the interposer, wherein the interposer includes a core and the plurality of spring elements are separated from the core by a plurality of spaces defined by the core.

Clause 27: The method according to either of clauses 26 or 27, further including fabricating a plurality of walls on the interposer, wherein the plurality of walls define a plurality of cavities configured to distribute mechanical stresses between the sensor die and the substrate.

Clause 28: The method according to any one of clauses 25-27, further including fabricating an electrical interposer including a plurality of electrical interconnects, wherein each of the plurality of interconnects electrically is configured to couple at least a portion of the sensor die to a portion of the circuit.

Clause 29: The method according to any one of clauses 25-28, further including: positing a temperature sensor between the sensor die and the circuit; and electrically coupling a thermal controller to the temperature sensor, wherein the thermal controller is configured to compensate for temperature changes in the sensor die and the circuit.

All patents, patent applications, publications, or other disclosure material mentioned herein, are hereby incorporated by reference in their entirety as if each individual reference was expressly incorporated by reference respectively. All references, and any material, or portion thereof, that are said to be incorporated by reference herein are incorporated herein only to the extent that the incorporated material does not conflict with existing definitions, statements, or other disclosure material set forth in this disclosure. As such, and to the extent necessary, the disclosure as set forth herein supersedes any conflicting material incorporated herein by reference and the disclosure expressly set forth in the present application controls.

The present invention has been described with reference to various exemplary and illustrative aspects. The aspects described herein are understood as providing illustrative features of varying detail of various aspects of the disclosed invention; and therefore, unless otherwise specified, it is to be understood that, to the extent possible, one or more features, elements, components, constituents, ingredients, structures, modules, and/or aspects of the disclosed aspects may be combined, separated, interchanged, and/or rearranged with or relative to one or more other features, elements, components, constituents, ingredients, structures, modules, and/or aspects of the disclosed aspects without departing from the scope of the disclosed invention. Accordingly, it will be recognized by persons having ordinary skill in the art that various substitutions, modifications or combinations of any of the exemplary aspects may be made without departing from the scope of the invention. In addition, persons skilled in the art will recognize, or be able to ascertain using no more than routine experimentation, many equivalents to the various aspects of the invention described herein upon review of this specification. Thus, the invention is not limited by the description of the various aspects, but rather by the claims.

Those skilled in the art will recognize that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although claim recitations are presented in a sequence(s), it should be understood that the various operations may be performed in other orders than those which are described, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

It is worthy to note that any reference to “one aspect,” “an aspect,” “an exemplification,” “one exemplification,” and the like means that a particular feature, structure, or characteristic described in connection with the aspect is included in at least one aspect. Thus, appearances of the phrases “in one aspect,” “in an aspect,” “in an exemplification,” and “in one exemplification” in various places throughout the specification are not necessarily all referring to the same aspect. Furthermore, the particular features, structures or characteristics may be combined in any suitable manner in one or more aspects.

As used herein, the singular form of “a”, “an”, and “the” include the plural references unless the context clearly dictates otherwise.

Directional phrases used herein, such as, for example and without limitation, top, bottom, left, right, lower, upper, front, back, and variations thereof, shall relate to the orientation of the elements shown in the accompanying drawing and are not limiting upon the claims unless otherwise expressly stated.

The terms “about” or “approximately” as used in the present disclosure, unless otherwise specified, means an acceptable error for a particular value as determined by one of ordinary skill in the art, which depends in part on how the value is measured or determined. In certain aspects, the term “about” or “approximately” means within 1, 2, 3, or 4 standard deviations. In certain aspects, the term “about” or “approximately” means within 50%, 200%, 105%, 100%, 9%, 8%, 7%, 6%, 5%, 4%, 3%, 2%, 1%, 0.5%, or 0.05% of a given value or range.

In this specification, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Any numerical range recited herein includes all sub-ranges subsumed within the recited range. For example, a range of “1 to 100” includes all sub-ranges between (and including) the recited minimum value of 1 and the recited maximum value of 100, that is, having a minimum value equal to or greater than 1 and a maximum value equal to or less than 100. Also, all ranges recited herein are inclusive of the end points of the recited ranges. For example, a range of “1 to 100” includes the end points 1 and 100. Any maximum numerical limitation recited in this specification is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited. All such ranges are inherently described in this specification.

Any patent application, patent, non-patent publication, or other disclosure material referred to in this specification and/or listed in any Application Data Sheet is incorporated by reference herein, to the extent that the incorporated materials is not inconsistent herewith. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those one or more elements. Likewise, an element of a system, device, or apparatus that “comprises,” “has,” “includes” or “contains” one or more features possesses those one or more features, but is not limited to possessing only those one or more features.

Instructions used to program logic to perform various disclosed aspects can be stored within a memory in the system, such as dynamic random access memory (DRAM), cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, compact disc, read-only memory (CD-ROMs), and magneto-optical disks, read-only memory (ROMs), random access memory (RAM), erasable programmable read-only memory (EPROM), electrically erasable programmable read-only memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the non-transitory computer-readable medium includes any type of tangible machine-readable medium suitable for storing or transmitting electronic instructions or information in a form readable by a machine (e.g., a computer).

As used in any aspect herein, the term “control circuit” may refer to, for example, hardwired circuitry, programmable circuitry (e.g., a computer processor including one or more individual instruction processing cores, processing unit, processor, microcontroller, microcontroller unit, controller, digital signal processor (DSP), programmable logic device (PLD), programmable logic array (PLA), or field programmable gate array (FPGA)), state machine circuitry, firmware that stores instructions executed by programmable circuitry, and any combination thereof. The control circuit may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, smart phones, etc. Accordingly, as used herein “control circuit” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

As used in any aspect herein, the term “logic” may refer to an app, software, firmware and/or circuitry configured to perform any of the aforementioned operations. Software may be embodied as a software package, code, instructions, instruction sets and/or data recorded on non-transitory computer readable storage medium. Firmware may be embodied as code, instructions or instruction sets and/or data that are hard-coded (e.g., nonvolatile) in memory devices.

As used in any aspect herein, the terms “component,” “system,” “module” and the like can refer to a computer-related entity, either hardware, a combination of hardware and software, software, or software in execution.

As used in any aspect herein, an “algorithm” refers to a self-consistent sequence of steps leading to a desired result, where a “step” refers to a manipulation of physical quantities and/or logic states which may, though need not necessarily, take the form of electrical or magnetic signals capable of being stored, transferred, combined, compared, and otherwise manipulated. It is common usage to refer to these signals as bits, values, elements, symbols, characters, terms, numbers, or the like. These and similar terms may be associated with the appropriate physical quantities and are merely convenient labels applied to these quantities and/or states.

A network may include a packet switched network. The communication devices may be capable of communicating with each other using a selected packet switched network communications protocol. One example communications protocol may include an Ethernet communications protocol which may be capable permitting communication using a Transmission Control Protocol/Internet Protocol (TCP/IP). The Ethernet protocol may comply or be compatible with the Ethernet standard published by the Institute of Electrical and Electronics Engineers (IEEE) titled “IEEE 802.3 Standard”, published in December, 2008 and/or later versions of this standard. Alternatively or additionally, the communication devices may be capable of communicating with each other using an X.25 communications protocol. The X.25 communications protocol may comply or be compatible with a standard promulgated by the International Telecommunication Union-Telecommunication Standardization Sector (ITU-T). Alternatively or additionally, the communication devices may be capable of communicating with each other using a frame relay communications protocol. The frame relay communications protocol may comply or be compatible with a standard promulgated by Consultative Committee for International Telegraph and Telephone (CCITT) and/or the American National Standards Institute (ANSI). Alternatively or additionally, the transceivers may be capable of communicating with each other using an Asynchronous Transfer Mode (ATM) communications protocol. The ATM communications protocol may comply or be compatible with an ATM standard published by the ATM Forum titled “ATM-MPLS Network Interworking 2.0” published August 2001, and/or later versions of this standard. Of course, different and/or after-developed connection-oriented network communication protocols are equally contemplated herein.

Unless specifically stated otherwise as apparent from the foregoing disclosure, it is appreciated that, throughout the foregoing disclosure, discussions using terms such as “processing,” “computing,” “calculating,” “determining,” “displaying,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

One or more components may be referred to herein as “configured to,” “configurable to,” “operable/operative to,” “adapted/adaptable,” “able to,” “conformable/conformed to,” etc. Those skilled in the art will recognize that “configured to” can generally encompass active-state components and/or inactive-state components and/or standby-state components, unless context requires otherwise.

The terms “proximal” and “distal” are used herein with reference to a clinician manipulating the handle portion of the surgical instrument. The term “proximal” refers to the portion closest to the clinician and the term “distal” refers to the portion located away from the clinician. It will be further appreciated that, for convenience and clarity, spatial terms such as “vertical”, “horizontal”, “up”, and “down” may be used herein with respect to the drawings. However, surgical instruments are used in many orientations and positions, and these terms are not intended to be limiting and/or absolute.

What is claimed is:

1. A sensor module comprising:
a sensor die comprising a microelectromechanical systems (“MEMS”) gyroscope resonator and an accelerometer positioned adjacent the MEMS gyroscope resonator;
a control circuit electrically coupled to the sensor die, wherein the control circuit is configured to receive signals from and control the MEMS gyroscope resonator and the accelerometer; and
an interposer positioned between and mechanically coupled to the sensor module and a substrate, wherein the interposer is configured to relieve stresses imposed by an operating environment on the sensor module and the substrate.

2. The sensor module of claim 1, wherein the interposer comprises a core and a plurality of spring elements separated from the core by a plurality of spaces defined by the core

3. The sensor module of claim 2, wherein the interposer defines a spring coefficient and is configured to distribute mechanical stresses between the sensor module and the substrate.

4. The sensor module of claim 1, wherein the interposer comprises a plurality of walls configured to define a plurality of cavities configured to distribute mechanical stresses between the sensor module and the substrate.

5. The sensor module of claim 4, wherein the plurality of cavities define a hexagonal configuration.

6. The sensor module of claim 1, wherein the interposer defines a surface area configured to enhance radiation of thermal energy generated between the sensor module and the substrate.

7. The sensor module of claim 1, further comprising an electrical interposer comprising a plurality of electrical interconnects, wherein each of the plurality of interconnects is configured to electrically couple at least a portion of the sensor die to a portion of the control circuit.

8. The sensor module of claim 6, wherein the electrical interposer has a coefficient of thermal expansion that is the same as a coefficient of thermal expansion of the sensor die and a coefficient of thermal expansion of the control circuit.

9. The sensor module of claim 1, further comprising:
a temperature sensor positioned between the sensor die and the control circuit; and
a thermal controller electrically coupled to the temperature sensor, wherein the thermal controller is configured to compensate for temperature changes in the sensor die and the control circuit.

10. The sensor module of claim 1, wherein the accelerometer is a resonant accelerometer that is co-fabricated with the MEMS gyroscope resonator.

11. An inertial measurement unit (IMU) comprising:
a plurality of single-axis sensor modules, wherein each of the plurality of single-axis sensor modules is mounted to a plurality of orthogonal surfaces, wherein each of the plurality of single-axis sensor modules is configured to be contained within a common enclosure, wherein each of the plurality of single-axis sensor modules comprises:
a sensor die comprising a microelectromechanical systems (“MEMS”) gyroscope resonator and an accelerometer positioned adjacent the MEMS gyroscope resonator;
a control circuit electrically coupled to the sensor die, wherein the control circuit is configured to receive signals from and control MEMS gyroscope resonator and the accelerometer; and
an interposer positioned between and mechanically coupled to the sensor module and a substrate, wherein the interposer is configured to relieve stresses imposed by an operating environment on the sensor module and the substrate.

12. The IMU of claim 10, wherein the plurality of single-axis sensor modules comprises three sensor modules, wherein each of the three sensor modules is orthogonally oriented relative to the other two sensor modules.

13. The IMU of claim 10, wherein the interposer comprises a core and a plurality of spring elements separated from the core by a plurality of spaces defined by the core.

14. The IMU of claim 12, wherein the interposer defines a spring coefficient and is configured to distribute mechanical stresses between the sensor module and the substrate.

15. The IMU of claim 10, wherein the interposer comprises a plurality of walls configured to create a plurality of cavities configured to distribute mechanical stresses between the sensor module and the substrate.

16. The IMU of claim 14, wherein the cavities are hexagonally configured.

17. The IMU of claim 10, wherein the interposer comprises a surface area configured to enhance radiation of thermal energy generated between the sensor module and the substrate.

18. The IMU of claim 10, further comprising an electrical interposer comprising a plurality of electrical interconnects, wherein each of the plurality of interconnects electrically couples at least a portion of the sensor die to a portion of the control circuit.

19. The IMU of claim 17, wherein the electrical interposer has a coefficient of thermal expansion that is the same as a coefficient of thermal expansion of the sensor die and a coefficient of thermal expansion of the control circuit.

20. The IMU of claim 10, further comprising:
a temperature sensor positioned between the sensor die and the control circuit; and
a thermal control element and electrically coupled to the temperature sensor, wherein the thermal controller is configured to compensate for temperature changes in the operating environment.

21. The IMU of claim 10, wherein the accelerometer is a resonant accelerometer that is co-fabricated with the MEMS gyroscope resonator.

22. A method of mitigating mechanical stresses within an inertial measurement unit (IMU), the method including:
monitoring, via a temperature sensor, a thermal condition within a sensor module, wherein the sensor module comprises a control circuit, and wherein the sensor module is mechanically separated from a substrate via an interposer; and
altering the thermal condition within the sensor module by controlling, via the control circuit, a heater positioned proximate to the sensor module.

23. The method of claim 20, further comprising:
electrically coupling, via an electrical interposer, the sensor module and the circuit from the substrate;
wherein the temperature sensor is positioned within the electrical interposer.

24. The method of claim 20, further comprising:
electrically coupling a portion of the sensor module to a portion of the circuit via a plurality of electrical interconnects.

25. A method of manufacturing an inertial measurement unit (“IMU”) subassembly, the method comprising:
fabricating a sensor module by co-fabricating on a sensor die a microelectromechanical systems (“MEMS”) gyroscope resonator and a accelerometer positioned adjacent the MEMS gyroscope resonator and electrically coupling a control circuit to the sensor die; and
positioning and mechanically coupling an interposer between the sensor module and a substrate, wherein the interposer is configured to relieve stresses imposed by an operating environment on the sensor module and the substrate.

26. The method of claim 23, further comprising fabricating a plurality of spring elements on the interposer, wherein the interposer comprises a core and the plurality of spring elements are separated from the core by a plurality of spaces defined by the core.

27. The method of claim 23, further comprising fabricating a plurality of walls on the interposer, wherein the plurality of walls define a plurality of cavities configured to distribute mechanical stresses between the sensor module and the substrate.

28. The method of claim 23, further comprising fabricating an electrical interposer comprising a plurality of electrical interconnects, wherein each of the plurality of interconnects electrically is configured to couple at least a portion of the sensor die to a portion of the control circuit.

29. The method of claim 23, further comprising:
positing a temperature sensor between the sensor die and the circuit; and
electrically coupling a thermal controller to the temperature sensor, wherein the thermal controller is configured to compensate for temperature changes in the sensor die and the control circuit.
